(19) United States
(12) Patent Application Publication
(10) Pub. No.: US 2026/0342329 A1
(43) Pub. Date: Oct. 29, 2026

(54) POWER-ON RESET CIRCUIT WITH SELF-DETECTION AND LATCHING AND ELECTRONIC DEVICE

(71) Applicant: Xiamen Industrial Technology Research Institute Co.,Ltd., Xiamen (CN)

(72) Inventors: Lixia Bai, Xiamen (CN); Guangwei Zhao, Xiamen (CN); Wenming Li, Hsinchu (TW); Meidong Liu, Xiamen (CN); Tianlong Pan, Xiamen (CN); Jiayu Yin, Xiamen (CN); Zhexin Zheng, Zhangzhou (CN); Hezuo Hong, Xiamen (CN)

(21) Appl. No.: 19/702,039

(22) Filed: Jun. 9, 2026

Related U.S. Application Data
(63) Continuation of application No. PCT/CN2026/096979, filed on May 14, 2026.

(30) Foreign Application Priority Data
Dec. 11, 2025 (CN) 202511869113.X

(51) Int. Cl. H03K 17/22; G01R 19/00; H03K 3/037; H03K 19/20

(52) U.S. Cl. CPC H03K 17/223; G01R 19/0038; H03K 3/037; H03K 19/20

(57) ABSTRACT

Provided is a power-on reset circuit with self-detection and latching, which includes a first detection unit, a second detection unit, and a logic comparison unit; a first RC charge and discharge unit is configured to detect and pre-charge a power supply voltage, and a first locking and closing unit is configured for locking and closing and signal locking to obtain a first detection voltage; a second RC charge and discharge unit is configured to detect and pre-charge the power supply voltage, and a second locking and closing unit is configured for locking and closing and signal locking to obtain a second detection voltage; by using a NAND gate of a logic unit, a corresponding reset signal is output based on the first detection voltage and the second detection voltage; this greatly reduces power consumption and reduces the overall circuit area.

### CROSS-REFERENCE TO RELATED APPLICATIONS

This application is a continuation of International Application No. PCT/CN2026/096979, filed on May 14, 2026, which claims priority to Chinese Patent Application No. 202511869113.X, filed on Dec. 11, 2025. Both of which are hereby incorporated by reference in their entireties.

### TECHNICAL FIELD

The present disclosure relates to the field of reset circuit technologies, and in particular, to a power-on reset circuit with self-detection and latching and an electronic device.

### BACKGROUND

In related technologies, existing power-on reset circuits detect Pbias and Nbias signals generated by internal Biasgen and start-up circuits. During the POR power-on reset process, it is necessary to wait for Pbias and Nbias to start before the POR starts detecting, then the node capacitors are charged and discharged, and finally power-on reset. During the startup process of the entire circuit, both the bias generator and the core circuit have their conduction paths turned on, resulting in significant power dissipation.

### SUMMARY

The present disclosure aims to at least partially solve one of the technical problems with the above-mentioned technology. Therefore, one objective of the present disclosure is to propose a power-on reset circuit with self-detection and latching, which avoids a risk of bias circuit self-starting through a RC charge and discharge unit and a locking and closing unit, and locks and shuts off a POR circuit, thereby greatly reducing power consumption and reducing the overall circuit area.

To achieve the above objectives, an embodiment of the present disclosure provides a power-on reset circuit with self-detection and latching, including: a first detection unit, which includes a first RC charge and discharge unit and a first locking and closing unit; the first RC charge and discharge unit is configured to detect and pre-charge a power supply voltage, and the first locking and closing unit is configured for locking and closing and signal locking to obtain a first detection voltage, a second detection unit, which includes a second RC charge and discharge unit and a second locking and closing unit; the second RC charge and discharge unit is configured to detect and pre-charge the power supply voltage, and the second locking and closing unit is configured for locking and closing and signal locking to obtain a second detection voltage, and a logic comparison unit, which includes a NAND gate, where a first input terminal of the NAND gate is connected to the first detection unit, a second input terminal of the NAND gate is connected to the second detection unit, and the NAND gate outputs a corresponding reset signal based on the first detection voltage and the second detection voltage; as a result, by using the RC charge and discharge unit and the locking and closing unit, the risk of bias circuit self-starting is avoided, and the POR circuit is locked and shutdown, thereby greatly reducing power consumption and reducing the overall circuit area.

Besides that, according to the embodiments of the present disclosure, the power-on reset circuit with self-detection and latching can also have the following additional technical features.

In some embodiments of the present disclosure, the first RC charge and discharge unit includes: a first Res resistor, where one end of the first Res resistor is connected to the power supply, and the other end of the first Res resistor serves as a first node, a second capacitor, where one end of the second capacitor is connected to the power supply, and the other end of the second capacitor is connected to the first node, and a fifth capacitor, one end of the fifth capacitor is connected to the power supply.

In some embodiments of the present disclosure, the first locking and closing unit includes: a first MOS transistor, where a drain of the first MOS transistor is connected to the other end of the fifth capacitor, and a source of the first MOS transistor is grounded; a second MOS transistor, where a source of the second MOS transistor is connected to the power supply, and a first transmission gate, where one end of the first transmission gate is connected to the other end of the second capacitor, and the other end of the first transmission gate is connected to the other end of the fifth capacitor.

In some embodiments of the present disclosure, the second RC charge and discharge unit includes: a second Res resistor, one end of the second Res resistor is grounded, and the other end of the second Res resistor serves as a second node, a fourth capacitor, one end of the fourth capacitor is grounded, and the other end of the fourth capacitor is connected to the second node, and a sixth capacitor, where one end of the sixth capacitor is grounded.

In some embodiments of the present disclosure, the second locking and closing unit includes: a third MOS transistor, a drain of the third MOS transistor is connected to the other end of the sixth capacitor, and a source of the third MOS transistor is connected to the power supply, a fourth MOS transistor, where a source of the fourth MOS transistor is grounded, and a second transmission gate, where one end of the second transmission gate is connected to the other end of the fourth capacitor, and the other end of the second transmission gate is connected to the other end of the sixth capacitor.

In some embodiments of the present disclosure, the first detection unit further includes: a first resistor, one end of the first resistor is connected to a drain of the second MOS transistor, a second resistor, one end of the second resistor is connected to the other end of the first resistor, and the other end of the second resistor is grounded, a first capacitor, where one end of the first capacitor is connected between the first resistor and the second resistor, and the other end of the first capacitor is grounded, and a fifth MOS transistor, where a gate of the fifth MOS transistor is connected between the first resistor and the second resistor, a source of the fifth MOS transistor is grounded, and a drain of the fifth MOS transistor is connected to the first node.

In some embodiments of the present disclosure, the second detection unit further includes: a third resistor, one end of the third resistor is connected to the power supply, a fourth resistor, one end of the fourth resistor is connected to the other end of the third resistor, a third capacitor, one end of the third capacitor is connected to the power supply, and the other end of the third capacitor is connected between the third resistor and the fourth resistor, and a sixth MOS transistor, where a gate of the sixth MOS transistor is connected between the third resistor and the fourth resistor, a source of the sixth MOS transistor is connected to the power supply, and a drain of the sixth MOS transistor is connected to the second node.

In some embodiments of the present disclosure, the logic comparison unit further includes a first inverter, a second inverter, and a third inverter, where an input terminal of the first inverter is connected to an output terminal of the first detection unit, an output terminal of the first inverter is connected to the first input terminal of the NAND gate, an input terminal of the second inverter is connected to an output terminal of the second detection unit, an output terminal of the second inverter is connected to an input terminal of the third inverter, and an output terminal of the third inverter is connected to the second input terminal of the NAND gate.

To achieve the above objectives, a second embodiment of the present disclosure provides an electronic device, including the power-on reset circuit with self-detection and latching as described above.

According to the embodiment of the present disclosure, the electronic device avoids the risk of bias circuit self-starting through the RC charge and discharge unit and the locking and closing unit, and locks and shuts off the POR circuit, thereby greatly reducing power consumption and reducing the overall circuit area.

### BRIEF DESCRIPTION OF DRAWINGS

FIG. 1 is a circuit structural schematic diagram of an existing power-on reset circuit with self-detection and latching.

FIG. 2 is a circuit structural schematic diagram of a power-on reset circuit with self-detection and latching according to an embodiment of the present disclosure.

FIG. 3 is a waveform diagram of the power-on reset circuit with self-detection and latching according to an embodiment of the present disclosure.

### DESCRIPTION OF EMBODIMENTS

The embodiments of the present disclosure are described in detail below, and examples of the embodiments are shown in the accompanying drawings, where the same or similar reference numerals throughout represent the same or similar elements or components with the same or similar functions. The embodiments described below with reference to the accompanying drawings are exemplary and intended to explain the present disclosure, and should not be construed as limiting the present disclosure.

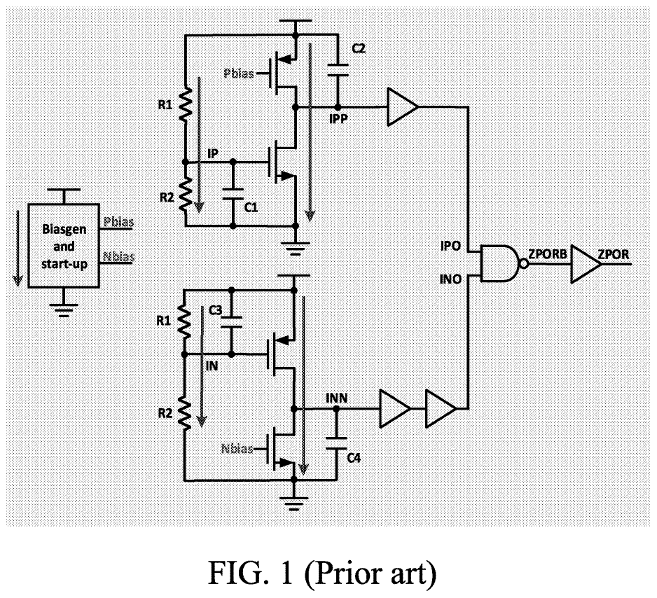

In related technologies, referring to FIG. 1, the POR start-up circuit in the prior art requires additional Biasgen and self-startup circuits for detection, and the overall circuit power consumption cannot be turned off, accounting for a large proportion of the overall chip power consumption; therefore, the present application provides a power-on reset circuit with self-detection and latching, which avoids a risk of bias circuit self-starting through a RC charge and discharge unit and a locking and closing unit, and locks and shuts off a POR circuit, thereby greatly reducing power consumption and reducing the overall circuit area.

In order to better understand the above technical solution, exemplary embodiments of the present disclosure will be described in more detail below with reference to the accompanying drawings. Although exemplary embodiments of the present disclosure are shown in the accompanying drawings, it should be understood that the present disclosure may be implemented in various forms and should not be limited by the embodiments described herein. On the contrary, these embodiments are provided to enable a more thorough understanding of the present disclosure and to fully convey the scope of the present disclosure to those skilled in the art.

In order to better understand the above technical solution, a detailed explanation of the above technical solution will be provided below in combination with the accompanying drawings in the specification and specific implementation modes.

The following will describe the power-on reset circuit with self-detection and latching according to an embodiment of the present disclosure with reference to the accompanying drawings.

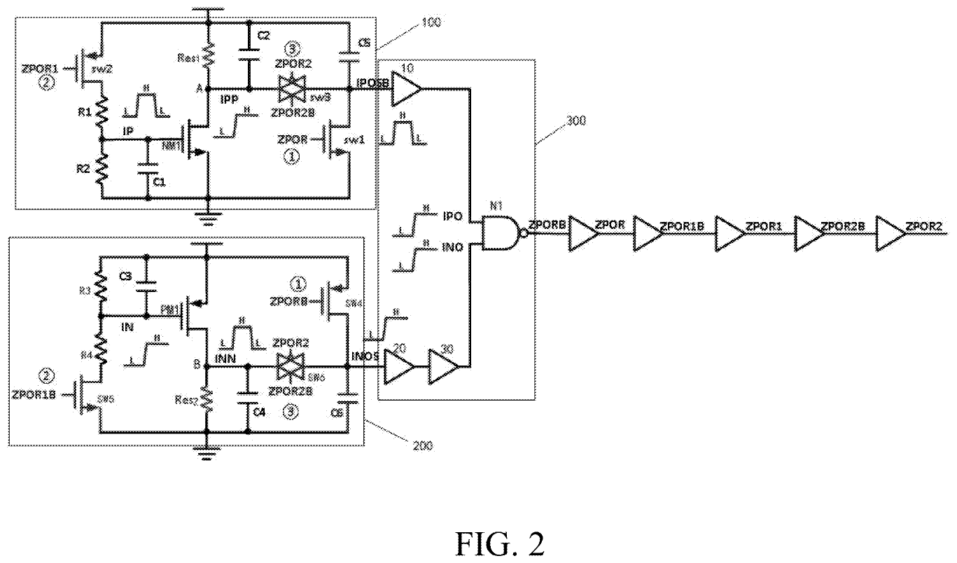

Referring to FIG. 2, the power-on reset circuit with self-detection and latching provided in the embodiment of the present disclosure includes a first detection unit 100, a second detection unit 200, and a logic comparison unit 300.

Where the first detection unit 100 includes a first Resistance-Capacitance, (RC) charge and discharge unit and a first locking and closing unit. The first RC charge and discharge unit is used for power supply voltage detection and pre charging, and the first locking and closing unit is used for locking and closing and signal locking to obtain a first detection voltage IPOSB.

In an implementation mode, the first RC charge and discharge unit includes a first Res resistor Res1, a second capacitor C2, and a fifth capacitor C5; one end of the first Res resistor Res1 is connected to a power supply, and the other end of the first Res resistor Res1 serves as a first node A; one end of the second capacitor C2 is connected to the power supply, and the other end of the second capacitor C2 is connected to the first node A; and one end of the fifth capacitor C5 is connected to the power supply.

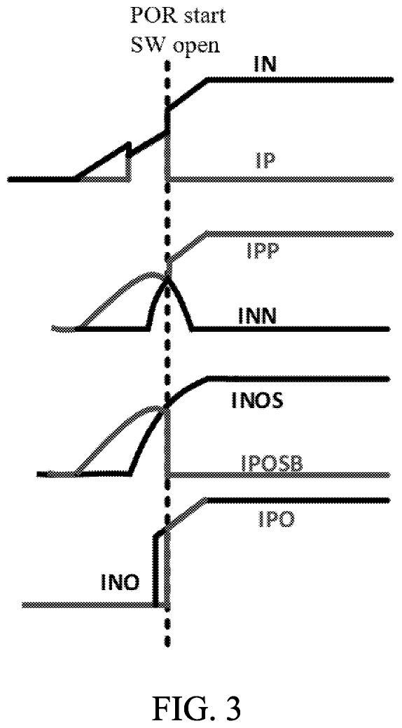

That is to say, referring to FIG. 3, a node voltage IPP is pre charged through the first Res resistor Res1, the second capacitor C2, and the fifth capacitor C5; the node voltage IPP changes from L to H, that is, from low level to high level; after POR starts, a switch SW in the circuit opens, and the IP voltage and IPOSB voltage change from H to L.

It should be noted that through RC charging and discharging delay, the power supply voltage (Voltage Drain Drain, (VDD)) is ensured to steadily rise to a Power-On Reset, (POR) startup threshold, avoiding false triggering caused by power supply fluctuations.

In an implementation mode, the first locking and closing unit includes a first Metal Oxide Semiconductor Field Effect Transistor, (MOS) transistor SW1, a second MOS transistor SW2, and a first transmission gate SW3; a drain of the first MOS transistor SW1 is connected to the other end of the fifth capacitor C5, and a source of the first MOS transistor SW1 is grounded; a source of the second MOS transistor SW2 is connected to the power supply; one end of the first transmission gate SW3 is connected to the other end of the second capacitor C2, and the other end of the first transmission gate SW3 is connected to the other end of the fifth capacitor C5.

That is to say, when the IPP voltage reaches the POR startup threshold, the circuit enters a latch stage, which shuts off the power consumption path and locks the reset signal through a three-step switch action.

It should be noted that after the POR circuit is started, step 1: open the first MOS transistor SW1 and pull IPOSB to VSS; step 2: open the second MOS transistor SW2, turn off a resistance path, and pull the IP to VSS; step 3: open the first transmission gate SW3 to cut off the path and prevent competition caused by pull-up; the POR is stable and latched, and all related power consumption has been turned off.

In an implementation mode, the first detection unit 100 further includes a first resistor R1, a second resistor R2, a first capacitor C1, and a fifth MOS transistor NM1; one end of the first resistor R1 is connected to a drain of the second MOS transistor SW2; one end of the second resistor R2 is connected to the other end of the first resistor R1, and the other end of the second resistor R2 is grounded; one end of the first capacitor C1 is connected between the first resistor R1 and the second resistor R2, and the other end of the first capacitor C1 is grounded; a gate of the fifth MOS transistor NM1 is connected between the first resistor R1 and the second resistor R2, a source of the fifth MOS transistor NM1 is grounded, and a drain of the fifth MOS transistor NM1 is connected to the first node A.

Where the second detection unit 200 includes a second RC charge and discharge unit and a second locking and closing unit. The second RC charge and discharge unit is used for power supply voltage detection and pre charging, and the second locking and closing unit is used for locking and closing and signal locking to obtain a second detection voltage INOS.

In an implementation mode, the second RC charge and discharge unit includes a second Res resistor Res2, a fourth capacitor C4, and a sixth capacitor C6; one end of the second Res resistor Res2 is grounded, and the other end of the second Res resistor Res2 serves as a second node B; one end of the fourth capacitor C4 is grounded, and the other end of the fourth capacitor C4 is connected to the second node B; and one end of the sixth capacitor C6 is grounded.

That is to say, referring to FIG. 3, the node voltage INN is pre charged through the second Res resistor Res2, the fourth capacitor C4, and the sixth capacitor C6. The node voltage INN changes from L to H, that is, from low level to high level. After POR starts, the switch SW in the circuit opens, and the INN voltage changes from H to L.

In an implementation mode, the second locking and closing unit includes a third MOS transistor SW4, a fourth MOS transistor SW5, and a second transmission gate SW6; a drain of the third MOS transistor SW4 is connected to the other end of the sixth capacitor C6, and a source of the third MOS transistor SW4 is connected to the power supply; a source of the fourth MOS transistor SW5 is grounded; one end of the second transmission gate SW6 is connected to the other end of the fourth capacitor C4, and the other end of the second transmission gate SW6 is connected to the other end of the sixth capacitor C6.

That is to say, when the INN voltage reaches the POR startup threshold, the circuit enters a latch stage, and the power consumption path is turned off, and the reset signal is locked through a three-step switch action. The voltage state is maintained through the node capacitor, and the reset signal is ensured by the switch logic, thereby providing reliable power on reset signals for other modules of the chip.

It should be noted that after the POR circuit is started, step 1: open the third MOS transistor SW4 and pull INOS to VDD; step 2: turn on the fourth MOS transistor SW5, turn off the resistance path, and pull IN to VDD; step 3: open the second transmission gate SW6, cut off the path, prevent the competition relationship caused by pull-down, stabilize the POR latch, and all related power consumption has been turned off.

In an implementation mode, the second detection unit 200 further includes a third resistor R3, a fourth resistor R4, a third capacitor C3, and a sixth MOS transistor PM1; one end of the third resistor R3 is connected to the power supply; one end of the fourth resistor R4 is connected to the other end of the third resistor R3; one end of the third capacitor C3 is connected to the power supply, and the other end of the third capacitor C3 is connected between the third resistor R3 and the fourth resistor R4; a gate of the sixth MOS transistor PM1 is connected between the third resistor R3 and the fourth resistor R4, a source of the sixth MOS transistor PM1 is connected to the power supply, and a drain of the sixth MOS transistor PM1 is connected to the second node B.

Where the logic comparison unit 300 includes a NAND gate N1, a first input terminal of the NAND gate N1 is connected to the first detection unit 100, and the second input terminal of the NAND gate N1 is connected to the second detection unit 200. The NAND gate N1 outputs a corresponding reset signal based on the first detection voltage IPOSB and the second detection voltage INOS.

In an implementation mode, the logic comparison unit 300 further includes a first inverter 10, a second inverter 20, and a third inverter 30. An input terminal of the first inverter 10 is connected to an output terminal of the first detection unit 100, an output terminal of the first inverter 10 is connected to the first input terminal of the NAND gate N1, an input terminal of the second inverter 20 is connected to an output terminal of the second detection unit 200, an output terminal of the second inverter 20 is connected to an input terminal of the third inverter 30, and an output terminal of the third inverter 30 is connected to the second input terminal of the NAND gate N1.

In an implementation mode, referring to FIG. 3, when the switch SW is turned on, the voltage state of each node: the node voltage IP changes from high level to low level; the node voltage IN changes from low level to high level; the node voltage IPP changes from low level to high level; the node voltage INN changes from high level to low level; the node voltage IPOSB changes from high level to low level; the node voltage INOS changes from low level to high level; the node voltage IPO changes from low level to high level. The node voltage INO changes from low level to high level.

Besides that, the signals of ZPOR, ZPOR1, ZPOR2, ZPORB, ZPOR1B, and ZPOR2B are the switch control signals of SW1, SW2, SW3, SW4, SW5, and SW6 in the figures respectively. It is a signal indicating a successful power-on of the circuit detection. Only after the power on is successful, will the local lockout be performed and the SW be turned off. Referring to FIG. 2, the detection signal ZPORB is a first signal, and the subsequent signals are delayed by a first stage inverter, that is, the time when the circuit locking and closing is turned off is marked as 1 (first turn off), 2, and 3 (last turn off) in the figures.

It should be noted that the inverter ensures that the signal input to the NAND gate N1 matches in timing, eliminates glitches or unstable states, and converts the analog voltage signal generated by capacitor charging and discharging into steep digital logic levels, thereby meeting the logic threshold requirements of the NAND gate N1 for the input signal.

In summary, according to the embodiments of the present disclosure, which provides the power-on reset circuit with self-detection and latching, where the first RC charge and discharge unit of the first detection unit is used for power supply voltage detection and pre charging, and the first locking and closing unit of the first detection unit is used for locking and closing and signal locking to obtain the first detection voltage; perform power supply voltage detection and pre charging through the second RC charge and discharge unit of the second detection unit, and perform locking and closing and signal locking through the second locking and closing unit of the second detection unit to obtain the second detection voltage; by the NAND gate of the logic comparison unit, the corresponding reset signal is output based on the first detection voltage and the second detection voltage; therefore, replacing the existing Pbias and Nbias detection with resistance Res detection can avoid the uncertainty risk caused by bias circuit startup. Due to the need for bias generation and start-up circuits, the circuit has high power consumption and will continue to consume high current after the overall circuit is powered on and reset. The present application locks the POR circuit, detects successful power on, locks and shuts off the circuit, greatly reducing power consumption and reducing the overall circuit area.

Furthermore, an embodiment of the present disclosure further provides an electronic device, including the power-on reset circuit with self-detection and latching as described above.

According to the embodiment of the present disclosure, the electronic device avoids the risk of bias circuit self-starting and locking and shutting off the POR circuit through the RC charge and discharge unit and the locking and closing unit, thereby greatly reducing power consumption and reducing the overall circuit area.

In the description of the present disclosure, it should be understood terms “center”, “longitudinal”, “transverse”, “length”, “width”, “thickness”, “up”, “down”, “front”, “back”, “left”, “right”, “vertical”, “horizontal”, “top”, “bottom”, “inside”, “outside”, “clockwise”, “counterclockwise” and other directional or positional relationships indicated are based on the directional or positional relationships shown in the accompanying drawings, only for the convenience of describing the present disclosure and simplifying the description, and do not indicate or imply that the device or element referred to must have a specific orientation, be constructed and operated in a specific orientation, and therefore cannot understand as a limitation on the present disclosure.

In addition, terms “first” and “second” are only used for descriptive purposes and cannot be understood as indicating or implying relative importance or implying the number of technical features indicated. Thus, the features limited to “first” and “second” may explicitly or implicitly include one or more of these features. In the description of the present disclosure, “multiple” means two or more, unless otherwise specifically limited.

In the present disclosure, unless otherwise specified and limited, the terms “installation”, “connection to”, “connection with”, “fixation”, etc. should be broadly understood, for example, it can be a fixed connection, a detachable connection, or integrated connected; it can be a mechanical connection or an electrical connection; it can be directly connected or indirectly connected through an intermediate medium, and it can be a connection within two components or an interaction relationship between two components. For those skilled in the art, specific meanings of the above terms in the present disclosure can be understood according to the specific situation.

In the present disclosure, unless otherwise specified and limited, the first feature above or below the second feature may include direct contact between the first and second features, or may include contact between the first and second features through another feature between them instead of direct contact. Moreover, the first feature being “above”, “up”, and “on” the second feature includes the first feature being directly above and diagonally above the second feature, or simply indicating that the first feature is horizontally higher than the second feature. The first feature being “below”, “down”, and “beneath” include the first feature being directly below and diagonally below the second feature, or simply indicating that the first feature has a lower horizontal height than the second feature.

In the description of this specification, the reference to the terms “one embodiment”, “some embodiments”, “examples”, “specific examples”, or “some examples” means that the specific features, structures, materials, or characteristics described in combination with the embodiment or example are included in at least one embodiment or example of the present disclosure. In this specification, the schematic expressions of the above terms should not be understood as necessarily referring to the same embodiments or examples. Moreover, the specific features, structures, materials, or characteristics described can be combined in any one or more embodiments or examples in a suitable manner. In addition, those skilled in the art can combine and join the different embodiments or examples described in this specification.

Although the embodiments of the present disclosure have been shown and described above, it can be understood that the above embodiments are exemplary and should not be construed as limiting the present disclosure. Those skilled in the art can make changes, modifications, substitutions, and variations to the above embodiments within the scope of the present disclosure.

What is claimed is:

1. A power-on reset circuit with self-detection and latching, comprising:
a first detection unit, which comprises a first Resistance-Capacitance, (RC) charge and discharge unit and a first locking and closing unit; the first RC charge and discharge unit is configured to detect and pre-charge a power supply voltage, and the first locking and closing unit is configured for locking and closing and signal locking to obtain a first detection voltage,
a second detection unit, which comprises a second RC charge and discharge unit and a second locking and closing unit; the second RC charge and discharge unit is configured to detect and pre-charge the power supply voltage, and the second locking and closing unit is configured for locking and closing and signal locking to obtain a second detection voltage, and
a logic comparison unit, which comprises a NAND gate, wherein a first input terminal of the NAND gate is connected to the first detection unit, a second input terminal of the NAND gate is connected to the second detection unit, and the NAND gate outputs a corresponding reset signal based on the first detection voltage and the second detection voltage;
wherein the first RC charge and discharge unit comprises:
a first Res resistor, wherein one end of the first Res resistor is connected to the power supply, and the other end of the first Res resistor serves as a first node,
a second capacitor, wherein one end of the second capacitor is connected to the power supply, and the other end of the second capacitor is connected to the first node, and
a fifth capacitor, one end of the fifth capacitor is connected to the power supply;
wherein the first locking and closing unit comprises:
a first MOS transistor, wherein a drain of the first MOS transistor is connected to the other end of the fifth capacitor, and a source of the first MOS transistor is grounded, a gate of the first MOS transistor is connected to a ZPOR signal to detect whether the circuit is successfully powered on based on the ZPOR signal;
a second MOS transistor, wherein a source of the second MOS transistor is connected to the power supply, a gate of the second MOS transistor is connected to a ZPOR1 signal to detect whether the circuit is successfully powered on based on the ZPOR1 signal, and
a first transmission gate, wherein one end of the first transmission gate is connected to the other end of the second capacitor, and the other end of the first transmission gate is connected to the other end of the fifth capacitor;
wherein the second RC charge and discharge unit comprises:
a second Res resistor, one end of the second Res resistor is grounded, and the other end of the second Res resistor serves as a second node,
a fourth capacitor, one end of the fourth capacitor is grounded, and the other end of the fourth capacitor is connected to the second node, and
a sixth capacitor, wherein one end of the sixth capacitor is grounded;
wherein the second locking and closing unit comprises:
a third MOS transistor, a drain of the third MOS transistor is connected to the other end of the sixth capacitor, and a source of the third MOS transistor is connected to the power supply, a gate of the third MOS transistor is connected to a ZPORB signal to detect whether the circuit is successfully powered on based on the ZPORB signal,
a fourth MOS transistor, wherein a source of the fourth MOS transistor is grounded, a gate of the fourth MOS transistor is connected to a ZPOR1B signal to detect whether the circuit is successfully powered on based on the ZPOR1B signal, and
a second transmission gate, wherein one end of the second transmission gate is connected to the other end of the fourth capacitor, and the other end of the second transmission gate is connected to the other end of the sixth capacitor.

2. The power-on reset circuit with self-detection and latching according to claim 1, wherein the first detection unit further comprises:
a first resistor, one end of the first resistor is connected to a drain of the second MOS transistor,
a second resistor, one end of the second resistor is connected to the other end of the first resistor, and the other end of the second resistor is grounded,
a first capacitor, wherein one end of the first capacitor is connected between the first resistor and the second resistor, and the other end of the first capacitor is grounded, and
a fifth MOS transistor, wherein a gate of the fifth MOS transistor is connected between the first resistor and the second resistor, a source of the fifth MOS transistor is grounded, and a drain of the fifth MOS transistor is connected to the first node.

3. The power-on reset circuit with self-detection and latching according to claim 1, wherein the second detection unit further comprises:
a third resistor, one end of the third resistor is connected to the power supply,
a fourth resistor, one end of the fourth resistor is connected to the other end of the third resistor, the other end of the fourth resistor is connected to a drain of the fourth MOS transistor,
a third capacitor, one end of the third capacitor is connected to the power supply, and the other end of the third capacitor is connected between the third resistor and the fourth resistor, and
a sixth MOS transistor, wherein a gate of the sixth MOS transistor is connected between the third resistor and the fourth resistor, a source of the sixth MOS transistor is connected to the power supply, and a drain of the sixth MOS transistor is connected to the second node.

4. The power-on reset circuit with self-detection and latching according to claim 1, wherein the logic comparison unit further comprises a first inverter, a second inverter, and a third inverter,
wherein an input terminal of the first inverter is connected to an output terminal of the first detection unit, an output terminal of the first inverter is connected to the first input terminal of the NAND gate, an input terminal of the second inverter is connected to an output terminal of the second detection unit, an output terminal of the second inverter is connected to an input terminal of the third inverter, and an output terminal of the third inverter is connected to the second input terminal of the NAND gate.

5. An electronic device, comprising the power-on reset circuit with self-detection and latching according to claim 1.
